(19) United States
(12) Patent Application Publication
(10) Pub. No.: US 2010/0025796 A1
(43) Pub. Date: Feb. 4, 2010

(54) Microchannel plate photocathode

(76) Inventor: Amir Massoud Dabiran, Chanhassen, MN (US)

Correspondence Address: KINNEY & LANGE, P.A., THE KINNEY & LANGE BUILDING, 312 SOUTH THIRD STREET, MINNEAPOLIS, MN, 55415-1002, US

(21) Appl. No.: 12/462,387

(22) Filed: Aug. 3, 2009

Related U.S. Application Data
(60) Provisional application No. 61/086,132, filed on Aug. 4, 2008.

(51) Int. Cl. H01L 31/0224; H01L 21/00

(52) U.S. Cl. 257/436; 438/71; 257/E31.002; 257/E31.124; 257/E21.002

(57) ABSTRACT

An energy-enhanced, low-temperature growth technique is used for direct deposition of periodic table column III nitrides-based negative electron affinity (NEA) photocathodes on standard glass microchannel plates (MCPs.) As working examples, low-temperature RF plasma-assisted molecular beam epitaxy growth (MBE) of p-type GaN layers on sapphire, quartz, and glass and alumina MCPs and their photoemission characterization is disclosed.

### CROSS-REFERENCE TO RELATED APPLICATION(S)

This application claims the benefit of Provisional Patent Application No. 61/086,132 filed Aug. 4, 2008 for III-NITRIDE PHOTOCATHODES DEPOSITED ON MICROCHANNEL PLATES.

### STATEMENT OF GOVERNMENT INTEREST

The U.S. Department of Energy provided funding under contract #DE-FG02-06ER84506. The Government has certain rights in this invention.

### BACKGROUND

This invention is in the technical field of image intensifiers and, more particularly, those that use microchannel plates (MCPs) as electron multipliers.

Microchannel plates (MCPs) are commonly used as electron intensifiers in UV, visible and infrared imaging detectors. A typical configuration of this type of photodetector comprises a photocathode to absorb incoming electromagnetic radiation in a range of wavelengths through photoemission processes to generate photoelectrons, and an MCP to amplify the generated photoelectrons with the resulting electrons received by either an optical or electronic image generation, or readout, arrangement. In recent years there have been significant improvements in the performance of these photodetectors by enhancements to the quantum efficiency (QE) of the detection process through improved photocathodes, advances in MCP performance characteristics, and developments of high performance image readout techniques.

Currently, the more common material for MCP fabrication is lead-silicate glass. The typical technology for modern production of lead glass MCPs is based on the use of optical fibers and involves multiple processes of dragging together and agglomerating fibers having an acid-soluble core, resulting in the production of a primary joined multiple fibers block. This block is then cut plural times at a desired angle across the direction of extent of the fibers, called a bias angle, to thereby be separated into joined multiple fibers plates that are then ground and polished across the ends of the fibers in the plates. Next, the cores are dissolved away before activating the MCP by a thermal reduction of lead-oxide in the surface area of channels under a hydrogen flow.

There are two common arrangements used for combining photocathodes with MCPs in sealed phototubes to form photodetectors. In a first arrangement (10), shown schematically in FIG. 1, a photocathode (13), which is a thin film of a photon responsive low electron-affinity material, is deposited on a suitable optical window (12) that is separated by a small vacuum gap (14) from the MCP (15), on top of a readout instrument (16), in a vacuum sealed phototube (17). A thin-film optical filter (11) is sometimes used on window (12) to either absorb or reflect, or both, a portion of the spectrum of the electromagnetic radiation impinging on that window. In this arrangement, further illustrated in the inset of FIG. 1, light enters by passing through filter (11) and window (12) to reach photocathode film (13) where photons with energy above a threshold, which depends on the photocathode material, are absorbed by generating photoelectrons. This first arrangement is typically referred to as a “semitransparent” or transmission mode photocathode.

The electrons generated in photocathode (13) by the impinging photons need to reach the surface thereof to be ejected into vacuum gap (14) from where they are guided into the microchannels of MCP (15) by an electric field applied between the photocathode and the MCP during operation. The electrons strike the facing MCP surfaces and are thereafter multiplied in number inside the microchannels by multiple collisions with channel walls (18) through secondary electron emission. In doing so, these electrons are accelerated by an electric field applied across the MCP channels until they exit the microchannels on the opposite side, and they thereafter typically either strike a phosphor screen (not illustrated) or are collected areally over a receiving surface in a readout arrangement (16) providing corresponding signals to readout circuitry therein to form an intensified image. A typical silica-glass MCP can provide a gain of up to about 103, and often two or more of these MCPs are stacked back-to-back in a phototube to obtain higher conversion gains and improved sensitivity.

In a second common photodetector arrangement (20), shown schematically in FIG. 2, the photodetector also may have an optical filter (21) deposited on a window (22) of a vacuum sealed phototube (27) and separated from the remainder of the structure by a vacuum gap (23). However, instead of being deposited on the back of window (23), a photocathode film (24) is directly deposited both on the surface and up to a certain depth on the microchannel walls (28) of a MCP (25), as shown in the inset of FIG. 2. In this arrangement, impinging photons having passed through window (22) and filter (21), if present, strike the facing surfaces of photocathode film (24) and, through photoemission, photoelectrons are generated and ejected from the same surface. This second arrangement is typically referred to as an “opaque” or reflection mode photocathode.

In this arrangement, the electrons that are ejected from the facing surfaces of photocathode film (24) on the outer surface or inside the microchannels of MCP (25) are guided down those microchannels by an electric field applied to the channels of MCP (25) during operation, with little chance of “crosstalk” between the channels because of photocathode electrons emitted in the vicinity of one microchannel traveling to another microchannel. A separate electrode (not shown) may be positioned outside MCP (25) to further help guide the photoelectrons into the microchannels. As in the first arrangement, electrons multiplied in number by secondary emission exiting the channels of MCP (25) typically either strike a phosphor screen (not illustrated) or are collected by a readout arrangement (26).

This second phototube arrangement has a number of advantages. First, the photocathodes in general show much higher detection quantum efficiency in the opaque mode (FIG. 2) as compared to those in the semitransparent mode (FIG. 1). This is mainly due to the semitransparent operation result of the photoelectrons being mostly generated in the back of the photocathode film (13) from where they need to reach the surface thereof facing MCP (15) before recombining with holes or being trapped by defects in that film. In many photocathodes, this requires films therefor that are thinner than the absorption length in the wavelength range of interest leading to photons not being absorbed thereby resulting in a lower quantum efficiency as compared to operation in the opaque mode. Furthermore, in the case of epitaxially grown semiconductor photocathode films (e.g., GaAs or GaN), the thicker films possible for opaque operation can result in higher crystal and optical qualities at the surface thereby resulting in further improvements in quantum efficiency.

Second, one of the important attributes of MCPs compared to other imaging technologies, such as charged coupled devices (CCDs), is the superior imaging resolution which is basically limited by the microchannel separation (˜10 μm). However, such imaging resolutions would not be possible for operation in the semitransparent mode since an electron ejected from a point on the surface of photocathode film (13), which is separated by vacuum gap (14) from MCP (15), could be transferred to a neighboring microchannel, as illustrated in the inset of FIG. 1. This effect will be more pronounced in the presence of any large electric or magnetic fields that could further modify the path of the photoelectrons. However, this effect can be virtually eliminated with the direct deposition of photocathode film (24) on MCP (25), since the emitted photoelectrons are generated near or inside of the microchannels with little chance of crosstalk between nearby channels, as illustrated in the inset of FIG. 2.

Finally, direct deposition of photocathode films on MCPs can lead to a more robust and lower cost production of phototubes by removing the need for expensive windows that are both transparent to the desired electromagnetic spectrum and compatible with high-quality deposition of photocathode materials. In this arrangement of FIG. 2, one may also use thin-film optical filters (21) deposited on the transparent window (22) to absorb the unwanted portion of electromagnetic spectrum (e.g., infrared and visible light in the case of UV imagers) to reduce the heating of photocathode film (24). In this structure, the heat generated by the absorption of light on the thermally conductive window (e.g., sapphire) can be removed via a good contact with cooled phototube housing (27).

In spite of the above important advantages, direct depositions of photocathodes on MCPs have been mainly limited to metallic layers, including alkali halides such as CsI, KBr, and MgF2, that can be deposited at lower temperatures. Compared to semiconductor photocathodes, such as GaAs or GaN, metallic photocathodes are generally more robust and have the advantage of air transportability. However, the main disadvantage of metallic photocathodes is that the quantum efficiency is relatively very low because of their high reflectivity and shallow electron escape depth.

Because of the negative electron affinity (NEA) that can be established for materials to be used in providing semiconductor photocathodes, such as those based on GaN thin films, those photocathodes used with MCPs can show relatively large quantum efficiencies, and with the added advantage of providing a sharp cutoff in photon absorption below their bandgap energies. GaN-based film photodetectors can the cutoff wavelength thereof moved into the deep ultraviolet portion of the electromagnetic spectrum by adding aluminum to the film composition (i.e., AlₓGal₁₋ₓN, with 0≦×≦1) or can have the cutoff wavelength occur in the visible and infrared portions by adding indium to the film composition (i.e., InₓGa₁₋ₓN, with 0≦×≦1.) The only drawback to the deposition of these semiconductor photocathodes directly on glass MCPs has been the required film deposition, or growth, temperatures that are well above the damage threshold of the materials used standard MCPs. Both low temperature growth and growth on glass surfaces have not been suitable conditions in which to obtain quality p-type conductivity GaN-based films thereon. As a result, these semiconductor photocathodes have been mostly grown on sapphire windows and then joined with glass MCPs to be used in conjunction with one another in sealed phototubes to be used in the semitransparent mode (FIG. 1) with the issues and problems described above. Thus, there is a need for a process that deposits GaN-based photocathode films directly on glass MCPs.

### SUMMARY

The present invention provides a method for providing a photocathode layer structure on a substrate of a substrate material differing from that the layers in the photocathode layer structure comprising heating the substrate to a temperature less than the thermal damage temperature of the substrate material, and depositing on the substrate a semiconductor material selected from magnesium doped GaN, AlGaN and InGaN, to thereby form thereon a growth layer with a growth surface, while increasing the energy of reactants at the growth surface from a source of energy external to the substrate without increasing the growth temperature of the substrate past the thermal damage temperature of the substrate material. This method allows for providing a photodetector having a microchannel plate having a periodic table column III nitride material photocathode on surfaces thereof having a microchannel plate having an end surface interrupted by a plurality of microchannels opening therein, a semiconductor material photocathode layer supported by the end surface and by sides of each of the plurality of microchannels with the semiconductor material being selected from magnesium doped GaN, AlGaN and InGaN, and a negative electron affinity material layer provided on the semiconductor material photocathode layer having a lower electron affinity than does the semiconductor material photocathode layer.

### BRIEF DESCRIPTION OF THE DRAWINGS

FIG. 1 shows a schematic diagram of a portion of a vacuum-sealed phototube known in the prior art;

FIG. 2 shows a schematic of a portion of a vacuum-sealed phototube embodying the present invention; and

FIG. 3 shows photoemission quantum efficiency (QE) for embodiments of the present invention and of the prior art.

### DETAILED DESCRIPTION

Disclosed herein is a process depositing periodic table column III nitrides (e.g., p-type GaN) on temperature limited substrates such as sapphire, silica glass, and porous glass and alumina using molecular beam epitaxy (MBE) in which the substrate surface reactants have energies enhanced from external energy sources to form deposited photocathodes on microchannel plates. Advantageously, RF plasma-assisted molecular beam epitaxy (MBE) is used for deposition of these photocathodes. Such photocathodes on sapphire, glass and alumina substrates exhibit relatively large detection quantum efficiencies (QE).

These photocathodes lead to substantial improvements in detection sensitivity, image resolution and service lifetime of imaging phototubes using them. Such processes can also be used for direct deposition of GaN-based photocathode films on other kinds of MCPs, including those based on aluminum-oxide for radiation-hard robust operation at elevated temperatures, and for low-cost large format detectors and imagers.

As an example only, a process of energy-enhanced, low-temperature deposition (e.g., RF plasma-assisted MBE) of semiconductor-based (e.g., p-type GaN) photocathode structures directly on microchannel plates (e.g., glass MCPs) is disclosed with the following steps: a) chemical and vacuum thermal cleaning of the MCP, b) heating the MCP in a vacuum chamber to a temperature less than a substrate material nature changing temperature, or thermal damage temperature, which, for glass, is typically at 300° C. to 350° C. or somewhat more depending on the type of glass, c) (advantageously, but not essentially) depositing, at a growth temperature of about 250° C., a thin layer of Al₂O₃ protective layer by atomic layer deposition, thereby forming a growth layer at a growth surface, to a final growth layer thickness of typically about 50 nm, and d) depositing, at a growth temperature of about 230° C., a p-type conductivity (Mg-doped) GaN semiconductor material layer (or p-type conductivity AlGaN or InGaN semiconductor material layer again achieved by Mg doping) by RF plasma-assisted MBE, thereby forming a growth layer on the end surface and inside the microchannels of the heated MCP at a growth surface, to a final growth layer thickness of typically about 0.5 μm to 1.0 μm. The Mg flux can be adjusted to produce useful p-type conductivity doping in the range of ˜5E17 to ˜2E19 holes/cm³. This process produced direct deposition of photocathodes on MCPs so that the higher QE of opaque mode operation can be utilized. Depending on the type of glass, growth temperature can be raised from ˜230° C., more preferably from a growth standpoint, to ˜300° C., and still more preferably ˜350° C.

Direct deposition of photocathodes on MCPs assembled in phototubes results in them having both higher imaging and higher temporal resolution as a result of photoemission events having the resulting emitted electrons occur in a MCP microchannel, or entering the nearest MCP microchannel from the MCP outer surface. This especially is the result of the deposited p-type conductivity GaN material for the photocathode being further treated to form a negative electron affinity (NEA) photocathode. The additional treatment is a) the activation of the GaN-based photocathode deposited on the MCP to achieve negative electron affinity through depositing a thin Cs film on the outer surface thereof in a ultra high vacuum, and b) thereafter the sealing of the photocathode deposited on the MCP and a readout circuit in a vacuum enclosure with a transparent window perhaps covered by an optional filter layer provided on the window.

In addition to enabling a band-pass response, the optional filter on the phototube window can be used reduces photocathode heating by absorbing unwanted (e.g., infrared) portions of the electromagnetic radiation incident on that window. Thus, with this deposition process, phototubes can be fabricated tuned to specific ranges of the electromagnetic spectrum by direct deposition of a photocathode on an MCP using a) selected adjustments to the composition of the photocathode material and/or structure (e.g., adding In or Al to GaN) to select within limits the portions of the spectrum represented in the electromagnetic radiation to which the photocathode responds, in combination with b) the selected spectrum passbands for any optical filters deposited on the phototube window that transmit impinging electromagnetic radiation.

This process of direct deposition of photocathodes on an MCP provides an improvement over the prior art because it allows fabrication in an integrated photocathode/MCP manufacturing operation with lower production costs, reduced complexity of construction, and removal of the requirement for providing epitaxial layers on compatible transparent windows, which in turn allows a wider selection of window materials, and of optical coatings that can be applied to either side of the window.

The invention also encompasses the phototube structure shown in FIG. 2 comprising a microchannel plate on which is deposited a photocathode, e.g., GaN or AlGaN or InGaN, as well as a complete phototube utilizing such structure. Optional layer (29) on microchannel wall (28) is a protective or nucleation layer for starting the semiconductor layer, or both, typically of Al₂O₃ or Si3N4 or AlN or others or combinations thereof, formed on the MCP by either physical deposition or vapor phase deposition. Depending on the MCP material type this layer can serve to 1) reduce the potential of contamination from the MCP (28) entering into photocathode layer (24) by covering it over as barrier, 2) increase the thermal stability of the MCP surface (28) at higher temperatures, 3) improve the chemical stability of the MCP in harsh environments, and 4) provide a more suitable surface for nucleating the start of the deposition of the photocathode layer (24). Layer (30) is a thin film of a low electron affinity material deposited on the photocathode layer (24) to induce negative electron affinity at the surface of the photocathode.

Molecular Beam Epitaxy (MBE) was used to produce working examples. In MBE, various atomic fluxes are generated by heating high-purity elemental materials (e.g., Ga or Al) in special ovens (called effusion cells) in an ultrahigh vacuum (UHV) chamber with base pressure of less than 5×10−11 Torr. The atomic fluxes converge on a heated substrate to form thin films of high-quality materials. For plasma-assisted III-Nitride MBE, an RF nitrogen plasma source was used to produce atomic nitrogen. RF plasma MBE was used to grow p-type GaN on sapphire at ˜650° C., and on quartz substrates and glass MCPs at temperatures of ˜250° C., which can be tolerated by standard glass MCPs. For one of the samples, an atomic layer deposition (ALD) system was used to deposit a thin layer of Al2O3 before growing the p-type GaN film. In situ monitoring techniques, such as optical reflectometry, pyrometry and electron diffraction, were used to monitor and control MBE growth at various stages.

The MBE system was a Perkin Elmer, Waltham, Mass., model PE-425-B, modified for III-nitride growth. (This is an older MBE system that is no longer commercially available, but is typical of the many that are available.) The effusion sources were models SVTA-SF-20-450 (for Mg), SVTA-HL-40-450 (for Ga), and SVTA-CL-20-450 (for Al), and the inductively-coupled RF nitrogen plasma source was a model SVT RF-4.50, and the ALD system was a model ALD-P-100B, all available from SVT Associates, Inc., Eden Prairie, Minn. The major MBE system modification was to add cryo-pumps to handle a higher nitrogen gas load and pressure and change the substrate heater to pyrolytic-boron nitride (PBN) for operating temperatures above 1000° C., but this was not needed for these examples for which all the equipment can be considered fairly conventional with equivalents available from other vendors as well.

Example no. 1: As an example of energy-enhanced growth techniques to deposit photocathodes directly on MCPs, low temperature growth of a GaN-based NEA photocathode film on silica glass was performed using RF plasma-assisted molecular beam epitaxy (MBE).

A commercially available polished quartz substrate (model: CGQ-0600-02) was obtained from ChemGlass, Inc. of Vineland, N.J., with a 1-inch (25 mm) diameter and ⅛ inch (3 mm) thickness. The substrate was cleaned first in acetone and then isopropanol baths, each for 5 minutes, then rinsed in DI water and blow dried using nitrogen gas. The substrate was then mounted on molybdenum sample holder and transferred to a UHV chamber and outgassed for 1 hour at ˜400° C. The substrate was them transferred to a vacuum-connected UHV MBE chamber and heated to ˜400° C. using the sample manipulator heater. Next, a nominally 0.1 μm thick Mg-doped GaN was grown on the substrate at a temperature of ˜380° C. while the substrate was rotated azimuthally at ˜10 RPM. The Mg and Ga fluxes were supplied using the effusion cells and the active nitrogen was supplied by the RF nitrogen plasma source. Based on previously done calibration runs for MBE growth of high quality p-type GaN on c-plane sapphire substrates, the nominal active nitrogen flux was set to produce ˜0.6 μm of GaN per hour, the Ga flux was adjusted for slightly Ga rich conditions, and the Mg flux was adjusted for high p-type doping of ˜5E18 holes/cm³. A very weak and diffused RHEED pattern indicated a mixture of amorphous and polycrystalline thin film deposited on the quartz substrate under these conditions. After growth, the p-type conductivity of the grown Mg-doped GaN layer was verified by hot-probe measurements and electrical measurements indicated ˜6 ohm-cm resistivity.

Example no. 2: This example was fabricated the same way as example 1 above except that, after chemical cleaning and before loading into the MBE system, ˜50 nm of Al₂O₃ was deposited on the surface at ˜250° C. using the ALD system. The ALD process to form each monolayer of Al₂O₃ included pulsed flooding of the ALD chamber with the aluminum precursor, tri-methyl-aluminum (TMA) from a metalorganic source bubbler for 1 sec, removing the residual precursor with nitrogen gas flushing and vacuum pumping, for 70 sec, pulsed flooding with H₂O vapor for 1 sec, and removing the residual water and any gas-phase reactants by a second nitrogen gas flushing and vacuum pumping for 130 sec. As in the case of example 1, a nominally 0.1 μm Mg-doped GaN layer was grown on this sample in the MBE chamber. Again, a very weak and diffused RHEED pattern indicated a mixture of amorphous and polycrystalline thin film deposited on the Al₂O₃ covered quartz substrate under these conditions. After the growth, the p-type conductivity of the grown Mg-doped GaN layer was verified by hot-probe measurements and electrical measurements indicated ˜3 ohm-cm resistivity.

Example no. 3: A lead-glass MCP (model: Detection Quality Long Life™, catalog # MCP 13/12/10/0 D 40:1 HD) was obtained from PHOTONIS USA, Inc., Sturbridge, Mass., with a ˜18 mm outside diameter, ˜13 mm quality diameter, ˜0.43 mm thickness, 10 μm nominal pore size, 12 μm nominal pore center-to-center spacing, ˜0 degree bias angle, and an open area ratio of ˜55%. The manufacturer was asked not to deposit electrode metal layers on either side of the MCP but to activate it using their typical hydrogen thermal reduction. The MCP was only cleaned by immersing in isopropanol followed by nitrogen gas drying and vacuum thermal cleaning at ˜250° C. for ˜2 hours to avoid possible chemical or thermal damage to the MCP. In the MBE system, ˜0.5 μm of Mg-doped GaN was grown on the MCP surface at a temperature of ˜230° C. Based on calibration runs for MBE growth of high quality p-type GaN on c-plane sapphire substrates, the nominal active nitrogen flux was set to produce ˜0.6 μm of GaN per hour, the Ga flux was adjusted for slightly Ga-rich conditions, and Mg flux was adjusted for high p-type doping of ˜5E18 holes/cm³. During MBE growth, the MCP was positioned on the MBE growth manipulator, using a molybdenum sample holder at an angle of ˜40 degrees with respected to the MBE sources, and was rotated azimuthally at a rate of ˜10 RPM in order to coat both the MCP surface and up to ˜20 μm inside of the microchannels with Mg-doped GaN. In this case also a very weak diffraction pattern on RHEED screen during and after growth indicated a mixture of amorphous and polycrystalline thin film deposited on the MCP.

All three samples were then transferred in air to the Space Science Group at the University of California at Berkeley (UCB) for photocathode activation and photoemission characterization. The UCB group performed minimal cleaning using immersion in a 1:1 solution of methanol and isopropanol and drying in a 90° C. oven to follow the procedures that would be compatible for processing of photocathodes grown on glass MCPs. Next the samples were transferred to a UHV chamber and baked to ˜350° C., with a slow ramp up and ramp down process typically taking ˜10 hours. To produce a negative electron affinity (NEA) cathode, the UCB group used the typical Cs-activation process which uses very slow (<0.1 ML/min) deposition of Cs on the p-GaN surface at ˜140° C. while measuring the photoemission signal by exposing the surface to UV light and collecting the photoelectrons by a Faraday cup. This process is continued until no further increase in the photoemission signal is observed which corresponds to optimized Cs layer thickness of about 1 ML. Next the photoemission QE was measured after calibrating the instrument using a previously characterized p-type GaN photocathode. This reference sample was an Mg-doped, ˜0.1 μm thick GaN film grown on 30 nm of AlN on c-plane sapphire at the typically higher substrate temperature of ˜550° C., which is not suitable for growth on glass MCPs.

The photoemission spectrum of the photocathode samples was also measured by the UCB group after Cs-activation, described above, in vacuum using a mercury lamp and monochrometer as the UV light source and a Faraday cup to collect the photoelectrons.

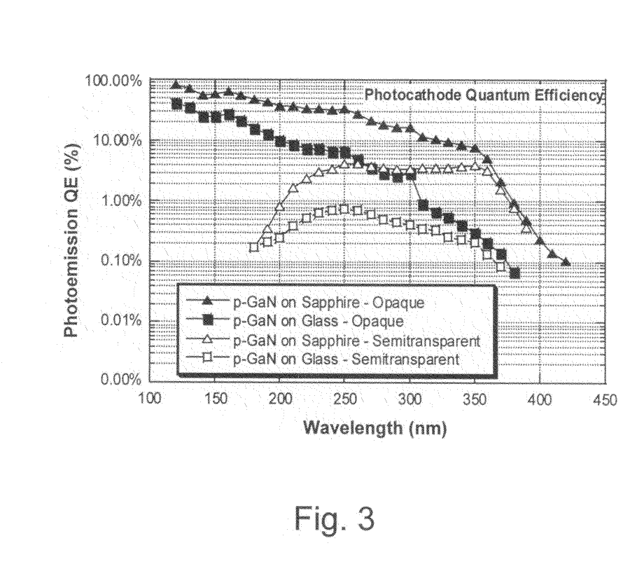

FIG. 3 shows the photoemission spectrum measured for p-type GaN (p-GaN) photocathodes grown on a various substrates. Example 2, the p-GaN on quartz with a thin Al₂O₃ coating (closed squares) was measured in the opaque mode. In this case, electrons were collected from the same side of the plate that was exposed to the incident light. Example 3, the p-GaN on an MCP, as illustrated in the inset of FIG. 2, (closed circles) was also measured in the opaque mode. The opaque mode results (not shown) for example 1, a quartz substrate without an Al₂O₃ coating, were very close to that of example 2. For comparison, FIG. 3 also shows these measurements in both opaque and semitransparent modes for the reference p-GaN photocathode on sapphire (closed triangles and open triangles, respectively).

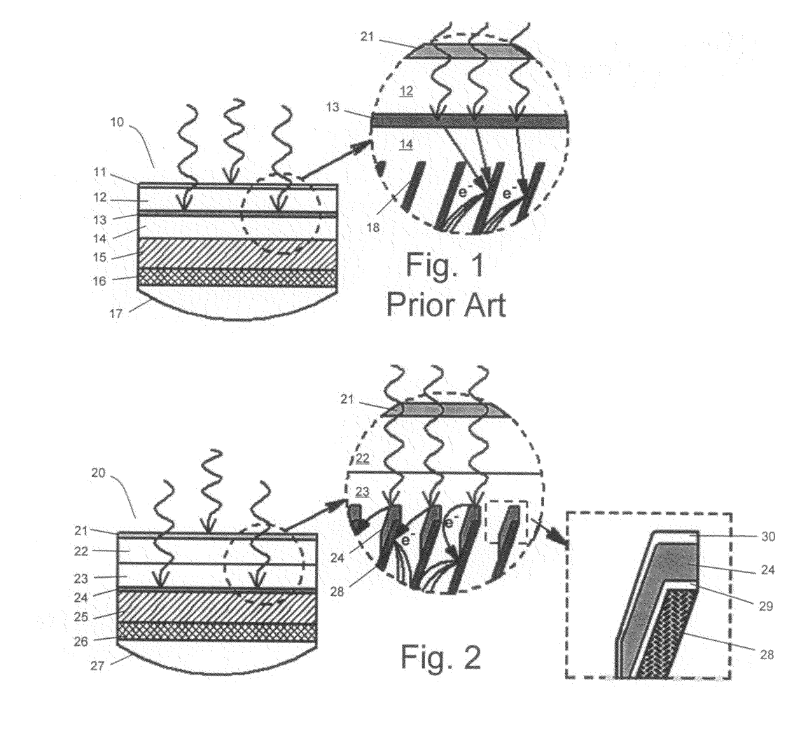

FIG. 3 shows photoemission quantum efficiency (QE) in opaque mode (closed symbols) for p-type GaN grown by RF plasma-assisted MBE on c-plane sapphire at ˜650° C. (triangles), quartz at ˜250° C. (squares), and on a glass MCP at ˜250° C. (circles). The open triangles in this figure correspond to QE measurements for the p-type GaN photocathode on c-plane sapphire measured in the semitransparent mode. As seen in FIG. 3, the sample grown on sapphire shows much higher QE as a function of wavelength, λ, in the opaque mode (e.g., QE>80% at λ ˜120 nm) compared to both samples grown on quartz and on MCP. However, as mentioned above, for integration in phototubes, photocathodes grown on a sapphire window must be used in the semitransparent mode (FIG. 1) which shows considerably lower QE (open triangles). These lower QE values are similar (for λ<250 nm) or substantially lower than the QE for operation in the opaque mode of the photocathode grown on quartz (closed squares) which indicates that similarly useful photocathode films can be directly deposited on MCPs (FIG. 2). Finally, FIG. 3 shows that deposition of p-GaN layers on MCPs with only mild cleaning, as described above, can still show detectable photoemission (closed circles), though with much lower QE than the case of growth on Al₂O₃-covered quartz (closed squares).

One of ordinary skill in the art will appreciate that routine experimentation will enable growth of a thin (˜50 nm) layer of Al₂O₃ formed by ALD over all the surfaces of a glass MCP. This will allow more aggressive cleaning of the MCP before deposition of GaN-based photocathode layers using low-temperature RF plasma-assisted MBE. The results for growth on Al₂O₃-covered quartz show that the proposed device should perform better than the current state-of-the-art UV phototubes containing the typical arrangement of a glass MCPs with a separate GaN-based photocathodes operated in the semitransparent mode.

Example no. 4: A bare alumina ceramic MCP, without an electron multiplication coating, with a 25 mm diameter and 0.1 mm thickness, was obtained from Synkera Technologies, Inc., Longmont, Colo. This MCP is fabricated from anodic aluminum oxide with heat treatment to produce gamma and alpha-alumina phases to improve chemical and thermal stability. This particular substrate had 25 μm pores with an open area ratio of about 25%. Surface preparation consisted of cleaning in an acetone bath for ˜5 min, followed by an isopropanol bath for ˜5 min, rinsing in DI water, immersion in (1:1) HCl:H₂O solution for ˜1 min, and a second DI water rinse. The substrate was then dried and baked in an oven at ˜200° C. in air before being transferred to the UHV preparation chamber and heated to ˜400° C. for ˜2 hours and then transferred to the MBE growth chamber and heated to ˜750° C. for ˜10 min.

The p-GaN photocathode layer growth steps were: 1) exposure of the surface to active nitrogen flux at ˜750° C. for 10 min using the RF nitrogen source at 400 W and a N₂ flow rate of 3 SCCM, 2) deposition of a 30 nm thick AlN layer at ˜750° C. under slightly Al-rich condition with RF nitrogen plasma source adjusted for ˜0.6 μm/hr, as explained above , and 3) deposition of a 0.5 μm thick Mg-doped GaN layer, under conditions similar to the working examples above. The substrate was heated to ˜750° C. and rotated at ˜10 RPM with the surface at an angle of ˜40 degrees with respect to the MBE sources during the growth to also produce, in this case, p-GaN coverage both on the surface and to some small depth inside of the alumina channels. A weak ringed RHEED pattern indicated mostly polycrystalline growth of p-GaN on the alumina MCP surface.

As with the other examples, this sample was shipped in air to UCB where it was Cs activated and its QE measured. The photoemission results were comparable to Example 1, being slightly lower at λ<200 nm (peak QE=20% vs. 30% at λ=120 nm). With reference to the inset in FIG. 2, alumina MCPs with a bias angle and open area ratios closer to the 55%, obtained with glass MCPs, should produce improved results. Alumina MCPs are of great interest for low-cost and large-format light detectors and imagers.

For the glass MCP sample, substrate temperatures were chosen on a very conservative basis to make sure that it survived the deposition. However, at least some glass material MCPs can be baked in vacuum at 380° C. While it cannot be predicted with certainty the temperature limit when using MBE, having demonstrated a working example at the lower temperatures, it should be possible to raise the substrate deposition temperatures to something approaching the vacuum bake temperatures, e.g., 300° C., more preferably from a growth standpoint, 350° C., before thermal damage occurs to the glass material in the MCP, i.e. before the MCP glass material structure or nature is changed due to overheating. Heating to temperatures close to, but below, the material thermal damage temperature should also prove useful for alumina MCPs coated for use as an electron multiplier.

Although the present invention has been described with reference to preferred embodiments, workers skilled in the art will recognize that changes may be made in form and detail without departing from the spirit and scope of the invention.

1. A method for providing a photocathode layer structure on a substrate of a substrate material differing from that the layers in the photocathode layer structure, the method comprising:
heating the substrate to a temperature less than the thermal damage temperature of the substrate material, and
depositing on the substrate a semiconductor material selected from magnesium doped GaN, AlGaN and InGaN, to thereby form thereon a growth layer with a growth surface, while increasing the energy of reactants at the growth surface from a source of energy external to the substrate without increasing the growth temperature of the substrate past the thermal damage temperature of the substrate material.

2. The method of claim 1 further comprising cleaning the substrate surface prior to depositing on the substrate a semiconductor material.

3. The method of claim 2 further comprising preceding the depositing on the substrate of a semiconductor material with depositing on the substrate a protective layer preventing diffusion therethrough from the substrate.

4. The method of claim 2 further comprising preceding the depositing on the substrate of a semiconductor material with depositing on the substrate a nucleating layer to promote starting the deposition of the semiconducting material growth layer to be supported on the substrate.

5. The method of claim 1 further comprising preceding the depositing on the substrate of a semiconductor material with depositing on the substrate a protective layer preventing diffusion therethrough from the substrate.

6. The method of claim 1 further comprising preceding the depositing on the substrate of a semiconductor material with depositing on the substrate a nucleating layer to promote starting the deposition of the semiconducting material growth layer to be supported on the substrate.

7. The method of claim 1 wherein the depositing on the substrate a semiconductor material is accomplished by radio frequency plasma assisted molecular beam epitaxy.

8. The method of claim 7 wherein the substrate is a microchannel plate.

9. The method of claim 1 wherein the substrate is a microchannel plate.

10. A method for providing a photocathode structure on a substrate, the method comprising:
a) chemical and vacuum thermal cleaning of the substrate;
b) heating the substrate in a vacuum chamber to ˜300° C.;
c) deposition of a thin (˜10 to ˜50 nm) of Al₂O₃ layer by ALD at ˜250° C.; and
d) deposition of p-type (Mg-doped) GaN (or AlGaN or InGaN) on the Al₂O₃ covered substrate by RF plasma-enhanced MBE at ˜230° C.

11. The method of claim 10 wherein the deposition of p-type (Mg-doped) GaN (or AlGaN or InGaN) on the Al₂O₃ covered substrate by RF plasma-enhanced MBE is at ˜300° C.

12. The method of claim 10 wherein the deposition of p-type (Mg-doped) GaN (or AlGaN or InGaN) on the Al₂O₃ covered substrate by RF plasma-enhanced MBE is at ˜350° C.

13. The method of claim 10 wherein the substrate is a microchannel plate.

14. A photodetector having a microchannel plate having a periodic table column III nitride material photocathode on surfaces thereof, the photodetector comprising:
a microchannel plate having an end surface interrupted by a plurality of microchannels opening therein,
a semiconductor material photocathode layer supported by the end surface and by sides of each of the plurality of microchannels with the semiconductor material being selected from magnesium doped GaN, AlGaN and InGaN, and
a negative electron affinity material layer provided on the semiconductor material photocathode layer having a lower electron affinity than does the semiconductor material photocathode layer.

15. The photodetector of claim 14 further comprising a protective layer between the semiconductor material photocathode layer and the end surface and between the semiconductor material photocathode layer and the sides of the plurality of microchannels.
